(19) United States
(12) Patent Application Publication
(10) Pub. No.: US 2025/0355049 A1
(43) Pub. Date: Nov. 20, 2025

(54) ESTIMATION DEVICE, ENERGY STORAGE APPARATUS, ESTIMATION METHOD, AND PROGRAM

(71) Applicant: GS Yuasa International Ltd., Kyoto-shi, Kyoto (JP)

(72) Inventors: Yusuke YOSHIOKA, Kyoto-shi, Kyoto (JP); Seiji TAKAI, Kyoto-shi, Kyoto (JP)

(21) Appl. No.: 18/729,425

(22) PCT Filed: Dec. 13, 2022
(86) PCT No.: PCT/JP2022/045755

§ 371 Date: Jan. 23, 2025

(30) Foreign Application Priority Data
Jan. 18, 2022 (JP) 2022-005802

(51) Int. Cl. G01R 31/367; G01R 31/389

(52) U.S. Cl. CPC G01R 31/367; G01R 31/389

(57) ABSTRACT

An estimation device 2 includes a control unit 21 that estimates charge acceptance performance or discharge performance of an energy storage apparatus 1 including a plurality of energy storage devices 3 and a conductive member. The control unit 21 acquires a current value of the energy storage apparatus 1 and a voltage value of the plurality of energy storage devices at an estimation time point, and estimates information on whether or not the energy storage apparatus 1 can be charged or discharged according to an assumed conduction pattern for a predetermined time from the estimation time point, by using the acquired current value, the acquired voltage value, and an energy storage apparatus model simulating behavior of the energy storage apparatus 1. The energy storage apparatus model includes a resistance component of the conductive member.

### TECHNICAL FIELD

The present invention relates to an estimation device, an energy storage apparatus, an estimation method, and a program.

### BACKGROUND ART

In recent years, the number of electronic devices mounted on a vehicle has been increasing for improvement in safety performance and ride comfort of an automobile. As representative examples, electronic devices for a start-stop function (idling stop function) for reducing a load on the environment and an autonomous driving function is mounted. With such a tendency, there is an increasing need for detection of a state of an energy storage apparatus for supplying electric power to electronic devices at an early stage and to predict whether or not electric power can be supplied.

Patent Document 1 discloses a battery control device capable of accurately calculating electric power that can be charged and discharged in a storage battery. In the battery control device described in Patent Document 1, chargeable and dischargeable power of a storage battery is calculated by assuming one storage battery as an electrical equivalent circuit and simulating charge-discharge behavior of the storage battery.

Patent Document 2 discloses a battery power prediction device that includes a unit cell calculation unit corresponding to each of battery cells and predicts allowable input and output power of the battery cell at low temperature.

### PRIOR ART DOCUMENTS

### Patent Documents

Patent Document 1: JP-A-2015-114135
Patent Document 2: JP-A-2016-126999

### SUMMARY OF THE INVENTION

### Problems to be Solved by the Invention

The technique described in Patent Document 1 is focusing on estimation of charge-discharge performance in one storage battery, and does not accurately estimate charge-discharge performance of an energy storage apparatus including a plurality of storage batteries (energy storage devices).

In Patent Document 2, a battery model of each unit cell is used, and there is room for improvement for accurate estimation of charge-discharge performance of an energy storage apparatus.

An object of the present disclosure is to provide an estimation device and the like capable of accurately estimating charge-discharge performance of an energy storage apparatus including a plurality of energy storage devices.

### Means for Solving the Problems

An estimation device according to one aspect of the present disclosure includes a control unit that estimates charge acceptance performance or discharge performance of an energy storage apparatus including a plurality of energy storage devices and a conductive member. The control unit acquires a current value of the energy storage apparatus and a voltage value of the plurality of energy storage devices at an estimation time point, and estimates information on whether or not the energy storage apparatus can be charged or discharged according to an assumed conduction pattern for a predetermined time from the estimation time point, by using the acquired current value, the acquired voltage value, and an energy storage apparatus model simulating behavior of the energy storage apparatus, and the energy storage apparatus model including a resistance component of the conductive member.

### Advantages of the Invention

According to the present disclosure, it is possible to accurately estimate charge-discharge performance of an energy storage apparatus including a plurality of energy storage devices.

### BRIEF DESCRIPTION OF THE DRAWINGS

FIG. 1 is a perspective view illustrating a configuration example of an energy storage apparatus 1 on which an estimation device according to an embodiment is mounted.

FIG. 2 is an exploded perspective view illustrating a configuration example of the energy storage apparatus 1.

FIG. 3 is a block diagram illustrating a configuration example of the energy storage apparatus 1.

FIG. 4 is a diagram for describing an estimation method for discharge performance in a case where an assumed conduction pattern is discharge.

FIG. 5 is a diagram for describing an estimation method for charge acceptance performance in a case where an assumed conduction pattern is charge.

FIG. 6 is a circuit diagram illustrating an example of an energy storage apparatus model of the energy storage apparatus 1.

FIG. 7 is a flowchart illustrating an example of an estimation processing procedure.

### MODE FOR CARRYING OUT THE INVENTION

Hereinafter, an outline of the present disclosure will be described.

(1) An estimation device includes a control unit that estimates charge acceptance performance or discharge performance of an energy storage apparatus including a plurality of energy storage devices and a conductive member. The control unit acquires a current value of the energy storage apparatus and a voltage value of the plurality of energy storage devices at an estimation time point, and estimates information on whether or not the energy storage apparatus can be charged or discharged according to an assumed conduction pattern for a predetermined time from the estimation time point, by using the acquired current value, the acquired voltage value, and an energy storage apparatus model simulating behavior of the energy storage apparatus and including a resistance component of the conductive member.

Here, the conductive member means a member structuring a conductive path (power line) in the energy storage apparatus other than the energy storage device. The conductive member may include a wiring member (for example, a wiring, a bus bars, and the like), a connection portion (for example, a welded portion or a connecting portion using a screw or the like) of the wiring member, a circuit breaker (for example, a semiconductor switch), and a current sensor (for example, a shunt resistor). The resistance component of the conductive member may be obtained by adding up resistance values of individual conductive members, or one or a plurality of resistance values may be experimentally obtained from a test circuit. A plurality of the resistance components of the conductive member may be prepared according to temperature.

The assumed conduction pattern may be, for example, a current pattern based on conduction time and an operating voltage range of the energy storage apparatus.

The information on whether or not the energy storage apparatus can be charged or discharged may include at least one of whether or not the energy storage apparatus can be charged or discharged according to an assumed conduction pattern, an allowable current value (allowable maximum current value) in the energy storage apparatus, and an estimated voltage value of the energy storage apparatus estimated using an energy storage apparatus model.

According to the configuration described in (1) above, by using an energy storage apparatus model instead of or in addition to a model (energy storage device model) for a single energy storage device, it is possible to appropriately estimate charge acceptance performance or discharge performance of the energy storage apparatus according to an assumed conduction pattern. By giving a resistance component of a conductive member to an energy storage apparatus model, in particular, a resistance component of the conductive member when large current flows through the energy storage apparatus can be taken into consideration, and estimation accuracy of information on whether or not the energy storage apparatus can be charged or discharged can be improved. Further, by giving voltage values of a plurality of energy storage devices to the energy storage apparatus model, it is possible to perform estimation in consideration of variation in a state of the energy storage devices.

In what is called a low-voltage battery such as a 12 volt (V) battery, a 24 V battery, or a 48 V battery, a total number of energy storage devices to be used is limited. In a low-voltage battery, a change in a state of charge (SOC) of each energy storage device per a predetermined time is large in a process of supplying electric power to many electronic devices and electric loads (as compared with that of each energy storage device in a high voltage battery for driving a vehicle). In order to avoid power loss, in particular, in a low-voltage battery, it is necessary to estimate whether or not charge or discharge according to an assumed conduction pattern is possible with high accuracy and short delay time (almost in real time). This need is increasing also for realization of an autonomous driving function of a vehicle.

According to the configuration described in (1) above, the estimation can be performed with high reliability in consideration of a resistance component (hereinafter, also referred to as structural resistance) of a conductive member and variation in a plurality of energy storage devices in order to simulate behavior of the entire energy storage apparatus. As in a low-voltage battery, in a case where a total number of energy storage devices is relatively small, internal resistance (for example, 10 mΩ) and structural resistance (for example, 2 mΩ) of the energy storage device are in the same order, and structural resistance cannot be ignored in estimation of whether or not conduction is possible, particularly appropriate estimation can be performed.

(2) In the estimation device according to (1) above, the estimation device may estimate an allowable current value of the energy storage apparatus by using the energy storage apparatus model and lower limit voltage or upper limit voltage of the energy storage apparatus.

Here, the lower limit voltage and the upper limit voltage of the energy storage apparatus may have a value given from a host device, or may have values sequentially given from a host device in real time. The lower limit voltage may be voltage by which operation of an electric load to which the energy storage apparatus is connected can be maintained (for example, 8 V in a 12 V battery). The upper limit voltage may be voltage allowable by a system (an electric load, a wiring member, and the like) to which the energy storage apparatus is connected (for example, 16 V in a 12 V battery).

In order to maintain stable operation of an electronic device and an electric load (for example, a sensor, an actuator, and the like necessary for driving a vehicle) that supply power from the energy storage apparatus when discharge from the energy storage apparatus is performed, it is required that voltage of the energy storage apparatus is not excessively lowered. For this reason, an allowable current value at which discharge from the energy storage apparatus is allowable is estimated using an energy storage apparatus model and lower limit voltage of the energy storage apparatus. Further, when the energy storage apparatus receives charge, it is necessary to prevent voltage of the energy storage apparatus from excessively increasing. For this reason, an allowable current value at which the energy storage apparatus can allow charge is estimated using an energy storage apparatus model and upper limit voltage of the energy storage apparatus. By using the allowable current value thus obtained, the estimation device can more appropriately estimate whether the energy storage apparatus can be charged or discharged according to an assumed conduction pattern.

Patent Document 2 described above predicts allowable input and output power of a unit cell, but does not disclose estimation of an allowable current value of an energy storage apparatus using lower limit voltage or upper limit voltage of the energy storage apparatus.

(3) The estimation device according to (1) or (2) above may give a smallest one of an allowable current value of the energy storage apparatus, an allowable current value of each energy storage device estimated using an energy storage device model simulating behavior of each energy storage device, and an absolute value of each protection current value for the energy storage apparatus to the energy storage apparatus model to obtain a voltage value of the energy storage apparatus after conduction in the assumed conduction pattern.

The allowable current value of each energy storage device may be estimated using an energy storage device model and lower limit voltage or upper limit voltage of the energy storage device.

The protection current value may be, for example, a current threshold that may lead to electrodeposition, overcurrent, or overtemperature in the energy storage device.

According to the configuration described in (3) above, a current value appropriately reflecting performance of the energy storage apparatus can be identified by considering a protection current value set in advance in addition to an allowable current value estimated from a present state of the energy storage apparatus or each energy storage device. A voltage value can be more appropriately estimated based on the identified current value.

(4) In the estimation device according to any of (1) to (3) above, the resistance component of the conductive member may be set according to at least any of temperature of the energy storage apparatus, the current value of the energy storage apparatus, and a drive voltage of a semiconductor switch which is a circuit breaker.

Structural resistance of the conductive member changes according to a change in temperature of the energy storage apparatus (ambient temperature of the conductive member). In a case where a field effect transistor (FET) is used as a circuit breaker, the structural resistance when the FET is turned on changes according to gate voltage and switch conduction current. According to the configuration described in (4) above, by appropriately correcting a value of a resistance component according to a situation, particularly appropriate estimation can be performed in a case where structural resistance cannot be ignored in estimation of whether or not conduction is possible.

(5) In the estimation device according to any of (1) to (3) above, the energy storage apparatus model may include a DC resistance component of each energy storage device.

According to the configuration described in (5) above, by giving a DC resistance component (internal resistance value) of each of a plurality of energy storage devices to an energy storage apparatus model, it is possible to perform estimation in consideration of variation in a state of the energy storage devices.

(6) An energy storage apparatus includes the estimation device according to any of (1) to (4) above, and a plurality of energy storage devices.

According to the configuration described in (6) above, by integrally including a plurality of the energy storage devices and the estimation device, proper estimation can be performed in substantially real time with less delay time by edge computing.

(7) The energy storage apparatus according to (6) above may be a 12 V battery, a 24 V battery, or a 48 V battery.

(8) An estimation method is an estimation method for estimating charge acceptance performance or discharge performance of an energy storage apparatus including a plurality of energy storage devices and a conductive member, the estimation method including: acquiring a current value of the energy storage apparatus and a voltage value of the plurality of energy storage devices at an estimation time point; and estimating information on whether or not the energy storage apparatus can be charged or discharged according to an assumed conduction pattern for a predetermined time from the estimation time point, by using the acquired current value, the acquired voltage value, and an energy storage apparatus model simulating behavior of the energy storage apparatus and including a resistance component of the conductive member.

(9) A program causes a computer that estimates charge acceptance performance or discharge performance of an energy storage apparatus including a plurality of energy storage devices and a conductive member to execute processing of: acquiring a current value and a voltage value of the plurality of energy storage devices at an estimation time point; and estimating information on whether or not the energy storage apparatus can be charged or discharged according to an assumed conduction pattern for a predetermined time from the estimation time point, by using the acquired current value, the acquired voltage value, and an energy storage apparatus model simulating behavior of the energy storage apparatus and including a resistance component of the conductive member.

Hereinafter, the present disclosure will be specifically described with reference to the drawings illustrating an embodiment of the present disclosure.

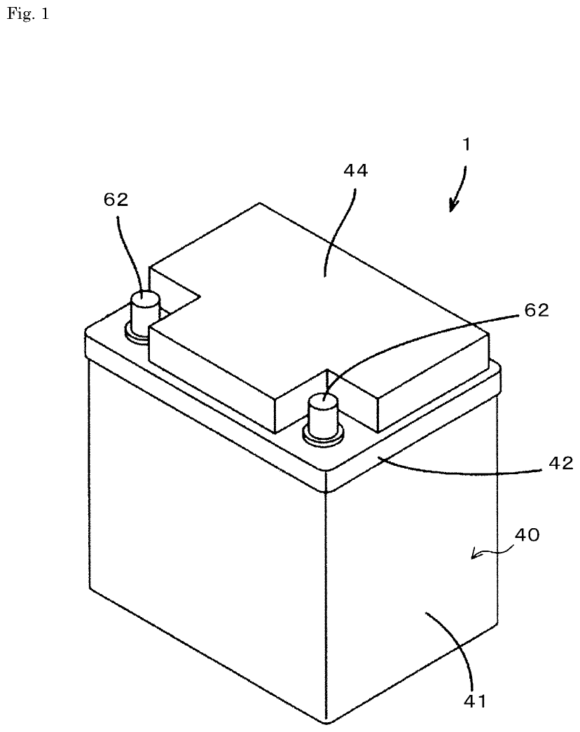

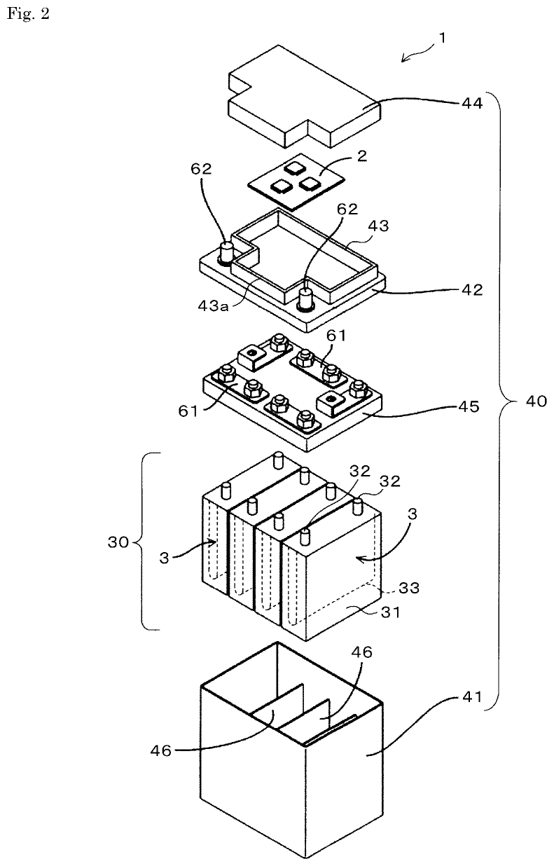

FIG. 1 is a perspective view illustrating a configuration example of an energy storage apparatus 1 on which an estimation device according to an embodiment is mounted, and FIG. 2 is an exploded perspective view illustrating a configuration example of the energy storage apparatus 1. The energy storage apparatus 1 is a 12 V power supply suitably mounted on, for example, an engine vehicle, an electric vehicle (EV), a hybrid electric vehicle (HEV), or a plug-in hybrid electric vehicle (PHEV).

The energy storage apparatus 1 includes an estimation device 2, a plurality of energy storage devices 3, and a rectangular parallelepiped housing case 40 which houses the estimation device 2 and the plurality of energy storage devices 3. The energy storage device 3 may be a battery cell such as a lithium ion secondary battery. The estimation device 2 is, for example, a battery management system (BMS).

Four of the energy storage devices 3 are connected in series to structure an assembled battery 30. Alternatively, some of the energy storage devices 3 may be connected in parallel. The assembled battery 30 may include, for example, twelve of the energy storage devices 3 including four of the energy storage devices 3 connected in series in each of three rows connected in parallel.

The housing case 40 is made from synthetic resin. The housing case 40 includes a case body 41, a lid body 42 that closes an opening portion of the case body 41, a housing portion 43 provided on an outer surface of the lid body 42, a cover 44 that covers the housing portion 43, an inner lid 45, and a partition plate 46. The inner lid 45 and the partition plate 46 do not need to be provided. The energy storage device 3 is inserted between the partition plates 46 of the case body 41.

A plurality of bus bars 61 made from metal are placed on the inner lid 45. The inner lid 45 is arranged in the vicinity of a terminal surface where a terminal 32 of the energy storage device 3 is provided, adjacent ones of the terminals 32 of adjacent ones of the energy storage devices 3 are connected by the bus bar 61, so that the energy storage devices 3 are connected in series. The bus bar 61 is an example of a conductive member. The bus bar 61 may be fixed to the terminal 32 of the energy storage device 3 on which a screw thread is formed by a nut as illustrated in FIG. 2, or may be fixed to the terminal 32 of the energy storage device 3 by welding. Since there are a large number of the bus bars 61 and connection portions between the bus bar 61 and the terminal 32, when, in particular, large current flows through the energy storage apparatus 1, a voltage drop caused by a resistance component of these becomes large.

The housing portion 43 has a box shape, and has a protruding portion 43a protruding outward at a central portion of one long side surface in plan view. A pair of external terminals 62 and 62 made from metal such as a lead alloy and having different polarities are provided on both sides of the protruding portion 43a on the lid body 42. The estimation device 2 is housed in the housing portion 43. That is, the housing case 40 houses the assembled battery 30 and the estimation device 2. The estimation device 2 is connected to the energy storage device 3 via a conductor (not illustrated). The estimation device 2 may be arranged, for example, adjacent to an upper side or a side of the assembled battery 30 instead of being housed in the housing portion 43.

The energy storage device 3 includes a case 31 having a hollow rectangular parallelepiped shape, and a pair of the terminals 32 and 32 having different polarities and provided on one side surface (terminal surface) of the case 31. The case 31 houses an electrode assembly 33 formed by stacking a positive electrode, a separator, and a negative electrode, and an electrolyte (electrolyte solution) (not illustrated).

Although details are not illustrated, the electrode assembly 33 is configured by placing a sheet-like positive electrode and negative electrode on each other with two sheet-like separators interposed between them and winding (longitudinally winding or laterally winding) them. The separator is formed of a porous resin film. As the porous resin film, a porous resin film made from resin such as polyethylene (PE) or polypropylene (PP) can be used.

The positive electrode is an electrode plate in which a positive active material layer is formed on a surface of an elongated strip-shaped positive electrode substrate made from, for example, aluminum, an aluminum alloy, or the like. The positive active material layer contains a positive active material. As the positive active material used for the positive active material layer, a material capable of occluding and releasing a lithium ion can be used. Examples of the positive active material include LiFePO₄. The positive active material layer may further contain a conductive assistant, a binder, and the like.

The negative electrode is an electrode plate in which a negative active material layer is formed on a surface of an elongated strip-shaped negative electrode substrate made from, for example, copper, a copper alloy, or the like. The negative active material layer contains a negative active material. As the negative active material, a material capable of occluding and releasing a lithium ion can be used. Examples of the negative active material include graphite, hard carbon, and soft carbon. The negative active material layer may further contain a binder, a thickener, and the like.

As an electrolyte housed in the housing case 40 together with the electrode assembly 33, the same electrolyte as that of a conventional lithium ion secondary battery can be used. For example, an electrolyte in which a supporting electrolyte is contained in an organic solvent can be used as the electrolyte. As the organic solvent, for example, an aprotic solvent such as carbonates, esters, and ethers is used. As the supporting electrolyte, for example, lithium salt such as LiPF₆, LiBF₄, or LiClO₄ is suitably used. The electrolyte may contain, for example, various additives such as a gas generating agent, a film forming agent, a dispersant, and a thickener.

FIGS. 1 to 2 illustrate, as an example of the energy storage device 3, a prismatic lithium ion battery including the electrode assembly 33 of a winding type. Alternatively, the energy storage device 3 may be a cylindrical lithium ion battery, a laminate type (pouch type) lithium ion battery or the like, or may include a stacked electrode assembly. The energy storage device 3 may be an all-solid-state lithium ion battery using a solid electrolyte.

The energy storage apparatus 1 according to the present embodiment is an in-vehicle low-voltage battery including the energy storage device 3 which is a lithium ion secondary battery. The energy storage device 3 may be an electrochemical cell or another secondary battery having a polarization characteristic.

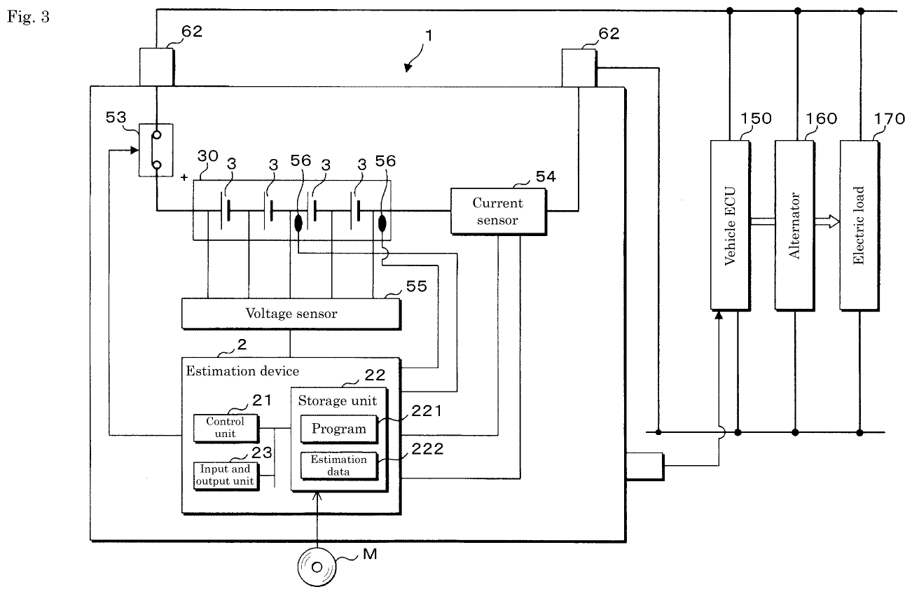

FIG. 3 is a block diagram illustrating a configuration example of the energy storage apparatus 1. The energy storage apparatus 1 includes the estimation device 2, the assembled battery 30, a circuit breaker 53, a current sensor 54, a voltage sensor 55, and a temperature sensor 56.

To the energy storage apparatus 1, a vehicle electronic control unit (ECU) 150, an alternator 160 which is power generation generated by power of an engine, and an in-vehicle electric load 170 are electrically connected via the external terminals 62 and 62.

The vehicle ECU 150 is a vehicle control unit that controls a vehicle. The vehicle ECU 150 controls the alternator 160 and the electric load 170. The vehicle ECU 150 controls charge voltage and an allowable charge-discharge amount of the energy storage apparatus 1 by controlling the alternator 160 and the electric load 170 based on an estimation result regarding charge-discharge performance received from the estimation device 2. The vehicle ECU 150 is an example of a “host device”.

In a case where a power generation amount of the alternator 160 is larger than a power consumption amount of the electric load 170 during driving of an engine, the energy storage apparatus 1 is charged by power (regenerative power) supplied from the alternator 160. When a power generation amount of the alternator 160 is smaller than a power consumption amount of the electric load 170, the energy storage apparatus 1 performs discharge in order to compensate for the shortage. While an engine is stopped, the alternator 160 stops power generation. While power generation is stopped, the energy storage apparatus 1 is in a state of not being charged, and is in a state of performing only discharge to the vehicle ECU 150 and the electric load 170. In a battery EV without an engine, a power converter (DC-DC converter) that converts high voltage into low voltage is used instead of the alternator 160.

The estimation device 2 is a flat-plate-shaped circuit board that estimates a state of each of the energy storage devices 3 at a predetermined timing and estimates charge-discharge performance of the energy storage apparatus 1. A shape of the estimation device 2 is not limited to a flat plate shape. The estimation device 2 may be configured as a circuit board unit in which the circuit breaker 53, the current sensor 54, the voltage sensor 55, and the like are mounted on a circuit board. The estimation device 2 includes a control unit 21, a storage unit 22, an input and output unit 23, and the like. By edge computing in which simulation described later is executed by the estimation device 2 in the energy storage apparatus 1 instead of the vehicle ECU 150, proper estimation can be performed in substantially real time with short delay time.

The control unit 21 is an arithmetic circuit including a central processing unit (CPU), a read only memory (ROM), a random access memory (RAM), and the like. The CPU included in the control unit 21 executes various computer programs stored in the ROM or the storage unit 22 and controls operation of each unit of the hardware described above, so as to cause the entire apparatus to function as the estimation device of the present disclosure. The control unit 21 may have a function of a timer that measures elapsed time from when a measurement start instruction is given to when a measurement end instruction is given, a counter that counts the number, a clock that outputs date and time information, and the like.

The storage unit 22 is a non-volatile storage device such as a flash memory. The storage unit 22 stores a program and data referred to by the control unit 21. The computer program stored in the storage unit 22 includes a program 221 for estimating information on whether or not the energy storage apparatus 1 can be charged or discharged. The data stored in the storage unit 22 includes estimation data 222 used for the program 221. The estimation data 222 includes an energy storage apparatus model of the energy storage apparatus 1 used in simulation. The energy storage apparatus model is described by configuration information indicating a circuit configuration, a value of each element structuring the energy storage apparatus model, and the like. The storage unit 22 stores configuration information indicating a circuit configuration of such an energy storage apparatus model, a value of each element structuring the energy storage apparatus model, and the like.

A computer program (computer program product) stored in the storage unit 22 may be provided by a non-transitory recording medium M in which the computer program is recorded in a readable manner. The recording medium M is a portable memory such as a CD-ROM, a USB memory, or a secure digital (SD) card. The control unit 21 reads a desired computer program from the recording medium M by using a reading device (not illustrated), and stores the read computer program in the storage unit 22. Alternatively, the computer program may be provided by communication. The program 221 can be loaded to be executed on a single computer or on a plurality of computers arranged on one site or distributed over a plurality of sites and interconnected by a communication network.

The input and output unit 23 includes an input and output interface for connecting an external device. The vehicle ECU 150, the circuit breaker 53, the current sensor 54, the voltage sensor 55, the temperature sensor 56, and the like are connected to the input and output unit 23.

The circuit breaker 53 includes, for example, a semiconductor switch such as an FET, a relay having a mechanical contact, and the like. The circuit breaker 53 cuts off current of the assembled battery 30 by switching between an on state and an off state according to a control signal output from the control unit 21.

The current sensor 54 is connected in series to the energy storage device 3. The current sensor 54 may be a shunt resistor. The current sensor 54 measures current flowing through the energy storage device 3 in time series based on terminal voltage of the energy storage device 3. Discharge and charge can be determined from polarity (positive or negative) of the terminal voltage. Alternatively, the current sensor 54 may be a magnetic sensor. The control unit 21 acquires current data measured by the current sensor 54 as needed through the input and output unit 23.

The voltage sensor 55 is connected in parallel to each of the energy storage devices 3. The voltage sensor 55 is connected to both ends of each of the energy storage devices 3, and measures voltage between terminals of each of the energy storage devices 3 in time series. The control unit 21 acquires data of voltage of each of the energy storage devices 3 and total voltage of the assembled battery 30 measured by the voltage sensor 55 as needed through the input and output unit 23.

The temperature sensor 56 is provided in the vicinity of the energy storage device 3 and detects temperature related to the energy storage apparatus 1. The temperature sensor 56 may be a thermocouple, a thermistor, or the like. Temperature related to the energy storage apparatus 1 may be, for example, temperature of electrolyte solution of the energy storage device 3, temperature around the energy storage device 3 or the energy storage apparatus 1, or the like. The control unit 21 acquires temperature data measured by the temperature sensor 56 as needed through the input and output unit 23.

In a case where an estimation result as to whether conduction is possible or not in the energy storage apparatus 1 is obtained, the control unit 21 outputs information based on the estimation result from the input and output unit 23 to the vehicle ECU 150. The vehicle ECU 150 executes various pieces of processing based on the information acquired from the estimation device 2.

The input and output unit 23 may include an interface for connecting a display device. An example of the display device is a liquid crystal display device. In a case where an estimation result as to whether conduction is possible or not in the energy storage apparatus 1 is obtained, the control unit 21 outputs information based on the estimation result from the input and output unit 23 to the display device. The display device displays an estimation result based on the information output from the input and output unit 23.

The input and output unit 23 may include a communication interface for communication with an external device. An external device communicably connected to the input and output unit 23 is a terminal device such as a personal computer or a smartphone used by the user, an administrator, or the like. In a case where an estimation result as to whether conduction is possible or not in the energy storage apparatus 1 is obtained, the control unit 21 transmits information based on the estimation result from the input and output unit 23 to a terminal device. The terminal device receives the information transmitted from the input and output unit 23, and displays an estimation result on a display of the terminal device based on the received information. The estimation device 2 may include a notification unit such as an LED lamp or a buzzer in order to notify the user of an estimation result as to whether or not conduction is possible in the energy storage apparatus 1.

FIGS. 1 to 3 illustrate an example in which the estimation device 2 is a BMS. Alternatively, the estimation device 2 may be arranged at a remote place. The estimation device 2 may include a server device located at a place remote from the energy storage device 3 and communicably connected to a BMS, or an ECU. A place where estimation as to whether conduction is possible or not is performed is not limited, and may be performed by, for example, a server device or an ECU.

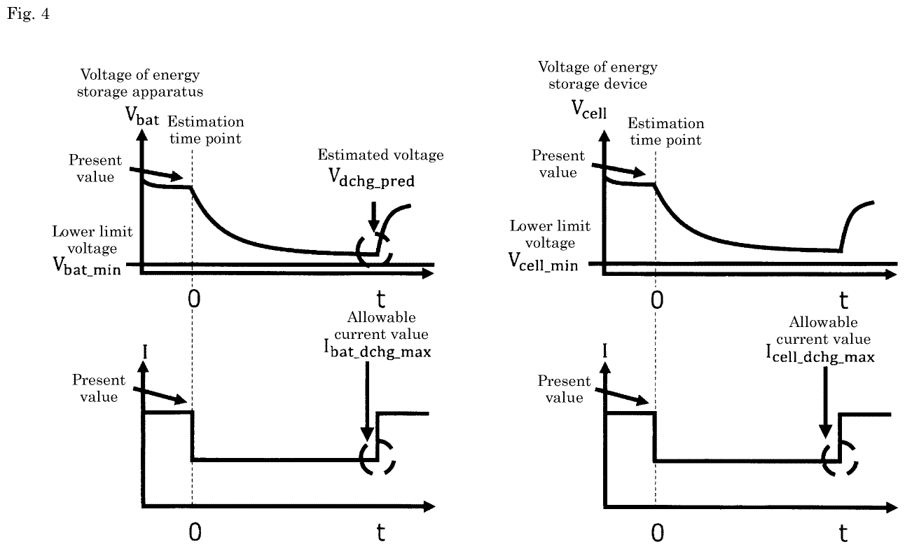

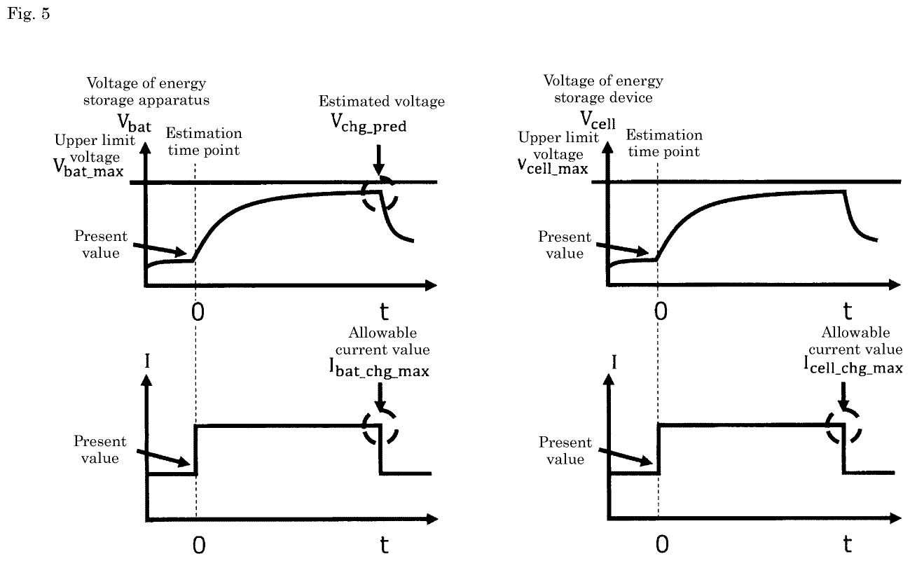

FIG. 4 is a diagram for describing an estimation method for discharge performance in a case where an assumed conduction pattern is discharge. FIG. 5 is a diagram for describing an estimation method for charge acceptance performance in a case where an assumed conduction pattern is charge. In FIGS. 4 and 5, an upper left graph shows a temporal change in a voltage value of the energy storage apparatus 1 due to conduction, and a lower left graph shows a temporal change in a current value of the energy storage apparatus 1 due to conduction. In FIGS. 4 and 5, an upper right graph shows a temporal change in a voltage value of the energy storage device 3 due to conduction, and a lower right graph shows a temporal change in a current value of the energy storage device 3 due to conduction.

A case where conduction is performed by a predetermined discharge current value for the energy storage apparatus 1 for a predetermined time (t seconds) with reference to an estimation time point is assumed. As illustrated in FIG. 4, when a discharge current value is constant, a voltage value of the energy storage apparatus 1 decreases due to discharge. Similarly, a voltage value of each of the energy storage devices 3 decreases due to discharge. In a case where estimated voltage after t seconds is larger than preset lower limit voltage of the energy storage apparatus 1, it can be determined that conduction is possible. In a case where estimated voltage after t seconds is smaller than preset lower limit voltage of the energy storage apparatus 1, it can be determined that conduction is not possible.

Similarly, a case where conduction is performed by a predetermined charge current value for the energy storage apparatus 1 for a predetermined time with reference to an estimation time point is assumed. As illustrated in FIG. 5, when a charge current value is constant, a voltage value of the energy storage apparatus 1 increases due to charge. In a case where estimated voltage after t seconds is smaller than preset upper limit voltage of the energy storage apparatus 1, it can be determined that conduction is possible. In a case where estimated voltage after t seconds is larger than preset upper limit voltage of the energy storage apparatus 1, it can be determined that conduction is not possible.

In the present embodiment, first, a maximum current value at which estimated voltage after t seconds does not exceed lower limit voltage or upper limit voltage, that is, an allowable current value is obtained by using an energy storage apparatus model to be described later. At this time, not only for the energy storage apparatus 1 but also for each of the energy storage devices 3, an allowable current value that does not exceed lower limit voltage or upper limit voltage of each of the energy storage devices 3 is similarly obtained. Next, a final allowable current value for the energy storage apparatus 1 is identified based on the obtained allowable current value and another current protection value. Based on the identified allowable current value, it is determined whether or not an estimated voltage value in the energy storage apparatus 1 in a case where conduction is performed at the allowable current value is equal to or more than lower limit voltage or lower than upper limit voltage of the energy storage apparatus 1, so as to determine whether or not conduction is possible according to an assumed conduction pattern.

Hereinafter, an energy storage apparatus model of the present embodiment will be described, and then an estimation method for charge-discharge performance executed by the estimation device 2 of the present embodiment will be described in detail.

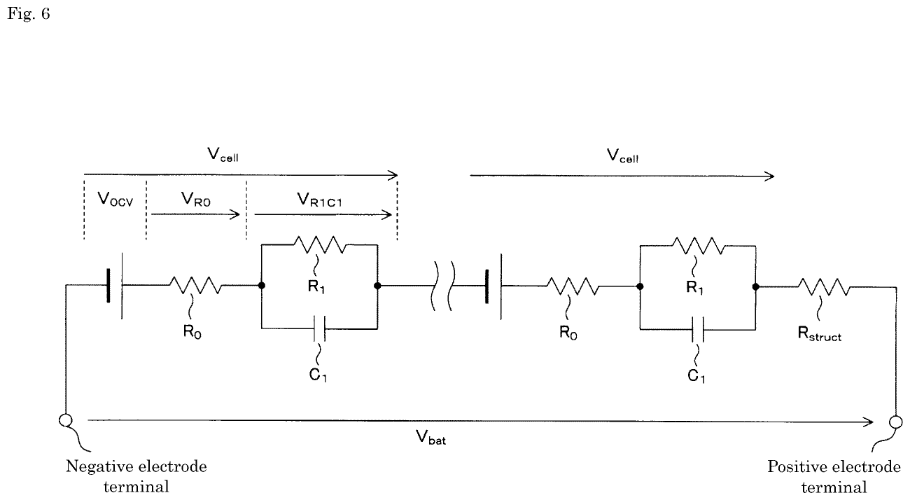

FIG. 6 is a circuit diagram illustrating an example of an energy storage apparatus model of the energy storage apparatus 1. An energy storage apparatus model illustrated in FIG. 6 as an example is an equivalent circuit model, and simulates a charge-discharge behavior of the energy storage apparatus 1 by combining a voltage source of the energy storage apparatus 1 including a plurality of the energy storage devices 3 and circuit elements such as a resistor and a capacitor.

In the example illustrated in FIG. 6, the equivalent circuit model includes n of the energy storage devices 3 (cells) connected in series between a positive electrode terminal and a negative electrode terminal, and a structural resistor. each of the energy storage devices 3 includes a constant voltage source, a DC resistor for simulating a DC resistance component, and an RC parallel circuit for simulating a transient polarization characteristic.

The structural resistor is for simulating a resistance component (structural resistance) of a conductive member in the energy storage apparatus 1, and includes a resistance element R_{struct}. The resistance element R_{struct} represents a resistance component in each of a plurality of members including, for example, the bus bar 61 and the circuit breaker 53. The resistance element R_{struct} may be given as a value that varies in accordance with temperature.

The constant voltage source is a voltage source (electromotive force) that outputs DC voltage. Voltage output from the constant voltage source is open circuit voltage (OCV) of the energy storage device 3 and is referred to as V_{OCV}. The V_{OCV} is given, for example, as a function of SOC. V_{OCV} may be given as a function of actual capacity (full charge capacity) of the energy storage apparatus 1.

The DC resistor simulates a DC resistance component (DC impedance) of the energy storage device 3, and includes a resistance element R₀. The resistance element R₀ is given as a value that fluctuates according to conduction current, voltage, an SOC, temperature, and the like. When impedance of the DC resistor is determined, voltage generated in the DC resistor when current I flows through the equivalent circuit model can be calculated. Voltage generated in the DC resistor is referred to as DC resistance voltage R₀I.

An RC parallel circuit includes a resistance element R₁ and a capacitance element C₁ connected in parallel. The resistance element R₁ and the capacitance element C₁ are given as values that fluctuate in accordance with an SOC, temperature, and the like of the energy storage device 3. Impedance of an RC parallel circuit is determined by the resistance element R₁ and the capacitance element C₁. When impedance of an RC parallel circuit is determined, voltage generated in the RC parallel circuit when the current I flows through this equivalent circuit model can be calculated. Voltage generated in an RC parallel circuit is referred to as polarization voltage V_{R1C1}.

The resistance elements R_{struct}, R₀, and R₁ and the capacitance element C₁ (hereinafter, also referred to as a circuit parameter) are obtained by a publicly-known method. A circuit parameter can be set, for example, in consideration of a relationship between temperature, SOC, and the like based on actual measurement data of a battery test. The estimation device 2 stores an obtained circuit parameter, temperature, an SOC, and the like in association with each other in the estimation data 222. A circuit parameter may be identified using an inspection result at the time of product shipment or a measurement value of a sensor after mounting of a product, or may be appropriately corrected (calibrated) based on a use history after mounting of a product.

The estimation device 2 estimates information on whether or not charge or discharge of the energy storage apparatus 1 can be performed according to an assumed conduction pattern for a predetermined time from an estimation time point using the equivalent circuit model configured as described above. Hereinafter, as an example, a process of estimation processing as to whether or not discharge is possible in the energy storage apparatus 1 in which four (n=4) of the energy storage devices 3 are connected in series will be described.

The estimation device 2 estimates whether or not discharge is possible using, for example, conduction time given from a host device and an operating voltage range of the energy storage apparatus 1 as an assumed conduction pattern. The operating voltage range is lower limit voltage of the energy storage apparatus 1 at the time of discharge, and upper limit voltage of the energy storage apparatus 1 is given at the time of charge.

From voltage sum rule, the polarization voltage V_{R1C1} of each of the energy storage devices 3 in a case where an estimation time point is t=0 can be estimated by Formula (1) below using terminal voltage V_{cell}, V_{OCV}, I, and R₀ of the energy storage device 3 generated at the time of discharge.

$$\begin{matrix}[ Math . 1 ] & \\ {V}_{R 1 C 1} ( 0 ) = {V}_{cell} ( 0 ) - {V}_{ocv} ( 0 ) - {R}_{0} I ( 0 ) & ( 1 )\end{matrix}$$

As the terminal voltages V_{cell} and I, a measurement value of the current sensor 54 and the voltage sensor 55 can be used. The current value I is, for example, a positive value in a case of charge, and is a negative value in a case of discharge. V_{OCV} can be calculated from an SOC at an estimation time point using, for example, an SOC·OCV table. The SOC may be calculated by a current integration method. The SOC·OCV table may be provided for each temperature, or a common table may be used. As the temperature, a measurement value of the temperature sensor 56 can be used. The polarization voltage V_{R1C1} may be obtained by, for example, a method such as a sequential least squares or Kalman filtering.

A case where conduction with the discharge current I (conduction according to an assumed conduction pattern) is performed for a predetermined time t seconds from an estimation time point is assumed. As illustrated in FIG. 6, voltage V_{bat} of the energy storage apparatus 1 is obtained by summing the terminal voltage V_{cell} of each of n of the energy storage devices 3 and voltage caused by a structural resistance component. Using an energy storage apparatus model, the voltage Vbat of the energy storage apparatus 1 at a time point after t seconds can be estimated by Formula (2) below using V_{OCV}, I, R₀, R₁, C₁, and R_{struct}.

$$\begin{matrix}[ Math . 2 ] & \\ {V}_{bat} = {\sum }_{cell 1}^{cell 4} {V}_{ocv} ( t ) + ( {R}_{struct} {\sum }_{cell 1}^{cell 4} {R}_{0} ) \times 1 + {\sum }_{cell 1}^{cell 4} \{ {R}_{1} I \times ( 1 - {exp}^{- \frac{t}{R 1 C 1}} ) + {V}_{R 1 C 1} ( 0 ) \times {exp}^{- \frac{t}{R 1 C 1}} \} & ( 2 )\end{matrix}$$

As the predetermined time t, conduction time provided from a host device can be used. V_{OCV}(t) at a time point after t seconds may be simply obtained by using V_{OCV}(0) at an estimation time point t=0 or may be obtained in consideration of an SOC change. At and after Formula (2), values corresponding to cell1 to cell4 are summed up, but a value of n may be appropriately changed corresponding to the number of the energy storage devices 3.

Further, voltage of each of the energy storage devices 3 at a time point after t seconds is estimated by using an energy storage device model that simulates behavior of each of the energy storage devices 3. The voltage V_{cell} of each of the energy storage devices 3 at a time point after t seconds can be estimated by Formula (3) below by using V_{OCV}, I, R₀, R₁, and C₁.

$$\begin{matrix}[ Math . 3 ] & \\ {V}_{cell} = {V}_{o c ν} ( t ) + {R}_{0} I + \{ {R}_{1} I \times ( 1 - {exp}^{- \frac{t}{R 1 C 1}} ) + {V}_{R 1 C 1} ( 0 ) \times {exp}^{- \frac{t}{R 1 C 1}} \} & ( 3 )\end{matrix}$$

Lower limit voltage in the energy storage apparatus 1 is defined as V_{bat_min}, and an allowable current value at the time of discharge in the energy storage apparatus 1 is defined as I_{bat_dchg_max}. The allowable current value I_{bat_dchg_max} means a maximum value of discharge current to the energy storage apparatus 1. In Formula (2), voltage of the energy storage apparatus 1 is assumed to reach V_{bat_min} when conduction with I_{bat_dchg_max} is performed for t seconds from an estimation time point (present time point). The allowable current value I_{bat_dchg_max} of the energy storage apparatus 1 can be estimated by Formula (4) below. As the lower limit voltage V_{bat_min}, lower limit voltage given from a host device can be used.

$$\begin{matrix}[ Math . 4 ] & \\ {I}_{bat \_ dchg \_ max} = [ {V}_{bat \_ min} - {\sum }_{cell 1}^{cell 4} ( {V}_{ocv} ( t ) + {V}_{R 1 C 1} ( 0 ) \times {exp}^{- \frac{t}{R 1 C 1 )}} ) ] / [ {R}_{s t r u c t} + {\sum }_{cell 1}^{cell 4} \{ {R}_{0} + {R}_{1} \times ( 1 - {exp}^{- \frac{t}{R 1 C 1}} ) \} ] & ( 4 )\end{matrix}$$

Similarly, lower limit voltage in each of the energy storage devices 3 is defined as V_{cell_min}, and an allowable current value at the time of discharge in each of the energy storage devices 3 is defined as I_{cell_dchg_max}. The allowable current value I_{cell_dchg_max} means a maximum value of discharge current for each of the energy storage devices 3. In Formula (3), voltage of each of the energy storage devices 3 is assumed to reach V_{cell_min} in a case where conduction with I_{cell_dchg_max} is performed for t seconds from an estimation time point. The allowable current value I_{cell_dchg_max} of each of the energy storage devices 3 can be estimated by Formula (5) below.

$$\begin{matrix}[ Math . 5 ] & \\ {I}_{cell \_ dchg \_ max} = \{ {V}_{cell \_ min} - ( {V}_{ocv} ( t ) + {V}_{R 1 C 1} ( 0 ) \times {exp}^{- \frac{t}{R 1 C 1}} ) \} / \{ {R}_{0} + {R}_{1} \times ( 1 - {exp}^{- \frac{t}{R 1 C 1}} ) \} & ( 5 )\end{matrix}$$

As the lower limit voltage V_{cell_min}, a threshold set in advance based on battery performance of each of the energy storage devices 3 can be used. The estimation device 2 acquires in advance, for example, lower limit voltage set from the viewpoint of preventing deterioration of the energy storage device 3 and upper limit voltage set from the viewpoint of preventing electrodeposition as thresholds of the energy storage devices 3, and stores the lower limit voltage and the upper limit voltage in the storage unit 22.

Based on the obtained allowable current value I_{bat_dchg_max} of the energy storage apparatus 1, the allowable current value I_{cell_dchg_max} of each of the energy storage devices 3, and various protection current values for the energy storage apparatus 1, the estimation device 2 identifies an allowable current value I_{dchg_max} at the time of final discharge with respect to an assumed conduction pattern. By the above, a current value of the assumed conduction pattern is determined. As the final allowable current value I_{dchg_max}, a smallest one of absolute values of I_{bat_dchg_max}, I_{cell_dchg_max}, and various protection current values may be selected.

I_{bat_dchg_max} and I_{cell_dchg_max} are values that fluctuate in accordance with a lower limit value of the energy storage apparatus 1 and each of the energy storage devices 3. The various protection current values are values that fluctuate in accordance with an ohmic loss and conduction time, and do not depend on a lower limit value of the energy storage apparatus 1 and each of the energy storage devices 3. Therefore, by setting a smallest allowable current value among them to the final allowable current value I_{dchg_max}, it is possible to perform discharge in which a state of the energy storage apparatus 1 and each of the energy storage devices 3 is maintained in an excellent manner.

Based on the obtained final allowable current value I_{dchg_max}, the estimation device 2 obtains estimated voltage V_{dchg_pred} at the time of discharge of the energy storage apparatus 1 in a case of conduction according to the assumed conduction pattern. Specifically, the estimated voltage V_{dchg_pred} can be estimated by Formula (6) below by substituting the allowable current value I_{dchg_max} into the equivalent circuit model expressed by Formula (3).

$$\begin{matrix}[ Math . 6 ] & \\ {V}_{dchg \_ pred} = {\sum }_{cell 1}^{cell 4} {V}_{ocv} ( t ) + ( {R}_{struct} + {\sum }_{cell 1}^{cell 4} {R}_{0} ) \times {I}_{dchg \_ max} + {\sum }_{cell 1}^{cell 4} \{ {R}_{1} {I}_{dcbg \_ max} \times ( 1 - {exp}^{- \frac{t}{R 1 C 1}} ) + {V}_{R 1 C 1} ( 0 ) \times {exp}^{- \frac{t}{R 1 C 1}} \} & ( 6 )\end{matrix}$$

Based on the obtained estimated voltage V_{dchg_pred}, the estimation device 2 determines whether or not conduction is possible according to the assumed conduction pattern. Specifically, the estimated voltage V_{dchg_pred} is compared with the lower limit voltage V_{bat_min} of the energy storage apparatus 1. In a case where the estimated voltage V_{dchg_pred} is equal to or more than the lower limit voltage V_{bat_min}, it is determined that conduction is possible. In a case where the estimated voltage V_{dchg_pred} is less than the lower limit voltage V_{bat_min}, it is determined that conduction is not possible. By the determination processing, appropriateness of the final allowable current value I_{dchg_max} can be checked.

The estimation device 2 outputs information corresponding to an estimation result to a host device such as a vehicle ECU. Based on the estimation result received from the estimation device, the host device determines whether or not each function such as an idling stop function and an autonomous driving function of a vehicle can be executed. By notifying the host device of an allowable current value estimated within restriction of conduction time and an operating voltage range and a determination result as to whether or not conduction is possible, the host device can perform determination according to an actual state of the energy storage apparatus 1. It is possible to predict a short-term voltage characteristic and power characteristic of the energy storage apparatus 1, what is called a state of function (SOF).

The example of a case in which an assumed conduction pattern is discharge is described above. The estimation device 2 similarly executes estimation processing as to whether or not conduction is possible also in a case where an assumed conduction pattern is charge. Hereinafter, a difference from the time of charge will be mainly described.

Upper limit voltage in the energy storage apparatus 1 is defined as V_{bat_max}, and an allowable current value at the time of charge in the energy storage apparatus 1 is defined as I_{bat_chg_max}. The allowable current value I_{bat_chg_max} means a maximum value of charge current to the energy storage apparatus 1. In Formula (2), voltage of the energy storage apparatus 1 is assumed to reach V_{bat_max} when conduction with I_{bat_chg_max} is performed for t seconds from an estimation time point (present time point). The allowable current value I_{bat_chg_max} of the energy storage apparatus 1 can be estimated by Formula (7) below. As the upper limit voltage V_{bat_max}, upper limit voltage given from a host device can be used.

$$\begin{matrix}[ Math . 7 ] & \\ {I}_{bat \_ chg \_ max} = [ {V}_{bat \_ max} - {\sum }_{cell 1}^{cell 4} ( {V}_{ocv} ( t ) + {V}_{R 1 C 1} ( 0 ) \times {exp}^{- \frac{t}{R 1 C 1}} ) ] / [ {R}_{struct} + {\sum }_{cell 1}^{cell 4} \{ {R}_{0} + {R}_{1} \times ( 1 - {exp}^{- \frac{t}{R 1 C 1}} ) \} ] & ( 7 )\end{matrix}$$

Similarly, upper limit voltage in each of the energy storage devices 3 is defined as V_{cell}_max, and an allowable current value at the time of charge in each of the energy storage devices 3 is defined as I_{cell_chg_max}. The allowable current value I_{cell_chg_max} means a maximum value of charge current for each of the energy storage devices 3. In Formula (3) above, voltage of each of the energy storage devices 3 is assumed to reach V_{cell_max} in a case where conduction with I_{cell_chg_max} is performed for t seconds from an estimation time point. The allowable current value I_{cell_chg_max} of each of the energy storage devices 3 can be estimated by Formula (8) below.

$$\begin{matrix}[ Math . 8 ] & \\ {I}_{cell \_ chg \_ max} = \{ {V}_{cell \_ max} - ( {V}_{ocv} ( t ) + {V}_{R 1 C 1} ( 0 ) \times {exp}^{- \frac{t}{R 1 C 1}} ) \} / \{ {R}_{0} + {R}_{1} \times ( 1 - {exp}^{- \frac{t}{R 1 C 1}} ) \} & ( 8 )\end{matrix}$$

Based on the obtained allowable current value I_{bat_chg_max} of the energy storage apparatus 1, the allowable current value I_{cell_chg_max} of each of the energy storage devices 3, and various protection current values for the energy storage apparatus 1, the estimation device 2 identifies an allowable current value I_{chg_max} at the time of final charge with respect to an assumed conduction pattern. By the above, a current value of the assumed conduction pattern is determined. As the final allowable current value I_{chg_max}, a smallest one of absolute values of I_{bat_chg_max}, I_{cell_chg_max}, and various protection current values may be selected.

Based on the identified final allowable current value I_{chg_max}, the estimation device 2 obtains estimated voltage V_{chg_pred} at the time of charge of the energy storage apparatus 1 in a case where conduction is performed according to the assumed conduction pattern. Specifically, the estimated voltage V_{chg_pred} can be estimated by Formula (9) below by substituting the allowable current value I_{chg_max} into the equivalent circuit model expressed by Formula (3) above.

$$\begin{matrix}[ Math . 9 ] & \\ {V}_{cbg \_ pred} = {\sum }_{cell 1}^{cell 4} {V}_{ocv} ( t ) + ( {R}_{struct} + {\sum }_{cell 1}^{cell 4} {R}_{0} ) \times {I}_{chg \_ max} + {\sum }_{cell 1}^{cell 4} \{ {R}_{1} {I}_{chg \_ max} \times ( 1 - {exp}^{- \frac{t}{R 1 C 1}} ) + {V}_{R 1 C 1} ( 0 ) \times {exp}^{- \frac{t}{R 1 C 1}} \} & ( 9 )\end{matrix}$$

Based on the obtained estimated voltage V_{chg_pred}, the estimation device 2 determines whether or not conduction is possible according to the assumed conduction pattern. Specifically, the estimated voltage V_{chg_pred} is compared with the upper limit voltage V_{cell_max} of the energy storage apparatus 1. In a case where the estimated voltage V_{chg_pred} is less than the upper limit voltage V_{cell_max}, it is determined that conduction is possible. In a case where the estimated voltage V_{chg_pred} is equal to or more than the upper limit voltage V_{cell_max}, it is determined that conduction is not possible.

FIG. 6 illustrates an example of an equivalent circuit model (energy storage apparatus model) in which the energy storage apparatus 1 includes a plurality of the energy storage devices 3 connected in series. Alternatively, in a case where the energy storage apparatus 1 has a configuration in which a plurality of the energy storage devices 3 connected in parallel are further connected in series, the equivalent circuit model may be expressed by a set of a constant voltage source, a DC resistor, and an RC parallel circuit with a plurality of the energy storage devices 3 connected in parallel as one group. Alternatively, in the equivalent circuit model, a plurality of constant voltage sources, a DC resistor, and an RC parallel circuit may be connected in parallel so as to represent a plurality of the energy storage devices 3 connected in parallel. Further, RC parallel circuits in each of the energy storage devices 3 may be in two or more stages.

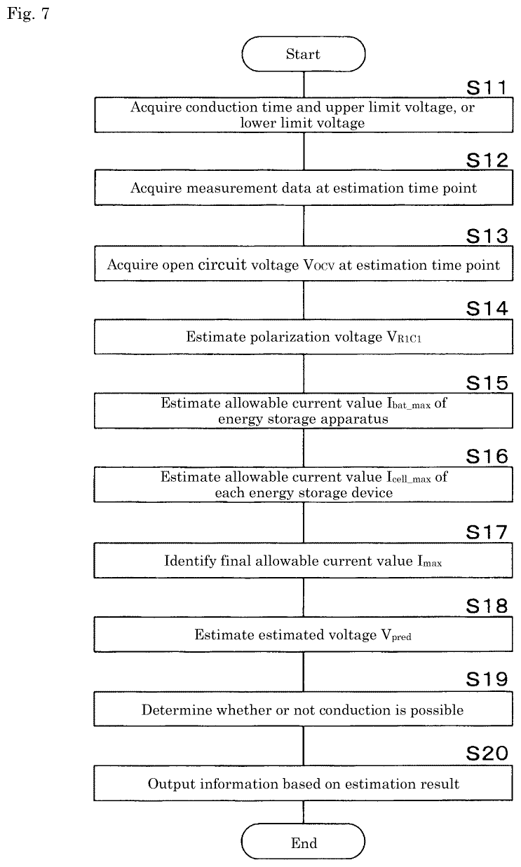

FIG. 7 is a flowchart illustrating an example of an estimation processing procedure. Processing below may be executed by the control unit 21 according to the program 221 stored in the storage unit 22 of the estimation device 2, may be realized by a dedicated hardware circuit (for example, FPGA or ASIC) provided in the control unit 21, or may be realized by a combination of these.

The control unit 21 executes processing below at predetermined or appropriate time intervals during use of a vehicle, for example. The control unit 21 may appropriately switch and execute estimation processing related to the discharge side and the charge side according to a direction of current flowing in and out of the energy storage apparatus 1.

The control unit 21 of the estimation device 2 acquires the conduction time t used for the estimation processing and the upper limit voltage V_{bat_max} or the lower limit voltage V_{bat_min} of the energy storage apparatus 1 (Step S11). For example, the control unit 21 may acquire conduction time and upper limit voltage or lower limit voltage transmitted from a host device by receiving them.

The control unit 21 acquires measurement data including a current value, a voltage value, and temperature of the energy storage apparatus 1 at an estimation time point through the input and output unit 23 (Step S12). The control unit 21 determines a conduction direction based on positive and negative of an obtained current value.

The control unit 21 acquires the open circuit voltage V_{OCV} of the energy storage apparatus 1 at an estimation time point based on the acquired measurement data (Step S13). Based on an SOC of the energy storage apparatus 1 obtained by, for example, a current integration method and an SOC·OCV table stored in the estimation data 222, the control unit 21 obtains the open circuit voltage V_{OCV} corresponding to an SOC at an estimation time point.

The control unit 21 estimates the polarization voltage V_{R1C1} of each of the energy storage devices 3 by Formula (1) above based on the acquired measurement data, the open circuit voltage V_{OCV}, and known various circuit parameters (Step S14). The control unit 21 may acquire a circuit parameter corresponding to an SOC, temperature, and the like at a time point of determination based on information stored in the estimation data 222. The circuit parameters include the resistance element R_{struct}, the DC resistance voltage R₀, the resistance element R₁, and the capacitance element C₁.

The control unit 21 estimates an allowable current value I_{bat_max} of the energy storage apparatus 1 (Step S15). Specifically, at the time of discharge, the control unit 21 substitutes the lower limit voltage V_{bat_min}, the open circuit voltage V_{OCV}, the polarization voltage V_{R1C1}, various circuit parameters, and the conduction time t into Formula (4) above to obtain the allowable current value I_{bat_dchg_max} by which voltage of the energy storage apparatus 1 reaches the lower limit voltage V_{bat_min} after t seconds from an estimation time point. Alternatively, at the time of charge, the control unit 21 obtains the allowable current value I_{bat_chg_max} by which voltage of the energy storage apparatus 1 reaches the upper limit voltage V_{bat_max} after t seconds from an estimation time point by Formula (7) above.

The control unit 21 estimates an allowable current value I_{cell_max} of each of the energy storage devices 3 (Step S16). Specifically, at the time of discharge, the control unit 21 substitutes the lower limit voltage V_{cell}_min, the open circuit voltage V_{OCV}, the polarization voltage V_{R1C1}, various circuit parameters, and the conduction time t into Formula (5) above to obtain the allowable current value I_{cell_dchg_max} by which voltage of each of the energy storage devices 3 reaches the lower limit voltage V_{cell_min} after t seconds from an estimation time point. Alternatively, at the time of charge, the control unit 21 obtains the allowable current value I_{cell_chg_max} by which voltage of each of the energy storage devices 3 reaches the upper limit voltage V_{cell_max} after t seconds from an estimation time point by Formula (8) above.

Based on the obtained allowable current value I_{bat_max} of the energy storage apparatus 1, the allowable current value I_{cell_max} of each of the energy storage devices 3, and various protection current values for the energy storage apparatus 1, the control unit 21 identifies a final allowable current value Imax with respect to an assumed conduction pattern (Step S17). The control unit 21 may identify the allowable current value Imax by selecting a smallest one among absolute values of I_{bat_chg_max}, I_{cell_chg_max}, and various protection current values.

The control unit 21 inputs the obtained final allowable current value Imax to an energy storage apparatus model to estimate estimated voltage V_{pred} of the energy storage apparatus 1 in a case where conduction is performed according to the assumed conduction pattern (Step S18). Specifically, at the time of discharge, the control unit 21 obtains the estimated voltage V_{dchg_pred} of the energy storage apparatus 1 after t seconds by substituting the final allowable current value I_{dchg_max}, the conduction time t, and the like into Formula (6) above. Alternatively, at the time of charge, the control unit 21 obtains the estimated voltage V_{chg_pred} of the energy storage apparatus 1 after t seconds by substituting the final allowable current value I_{chg_max}, the conduction time t, and the like into Formula (9) above.

Based on the obtained estimated voltage V_{pred}, the control unit 21 determines whether or not conduction by the assumed conduction pattern is possible (Step S19). The control unit 21 determines a magnitude relationship between the obtained estimated voltage V_{pred} and a predetermined threshold. At the time of discharge, in a case where the obtained estimated voltage V_{dchg_pred} is equal to or more than a threshold (lower limit voltage V_{bat_min}), the control unit 21 determines that discharge by the assumed conduction pattern is possible. At the time of charging, in a case where the obtained estimated voltage V_{chg_pred} is less than a threshold (upper limit voltage V_{cell_max}), the control unit 21 determines that charge acceptance by the assumed conduction pattern is possible.

The control unit 21 outputs information based on an estimation result to a host device via the input and output unit 23, and ends a series of processing (Step S20). The control unit 21 may output all of the final allowable current value Imax, the estimated voltage V_{pred}, and whether or not conduction is possible as information based on an estimation result, or may output at least one of them. The control unit 21 may return the processing to Step S11 and repeat the estimation processing.

According to the present embodiment, by use of an energy storage apparatus model, charge acceptance performance or discharge performance can be appropriately estimated in consideration of variation in a plurality of the energy storage devices 3 and a state of a conductive member of the energy storage apparatus 1. In particular, in an application where the energy storage device 3 is charged and discharged at a high rate (for example, a low-voltage battery application such as a 12 V battery), a voltage drop due to resistance of a conductive member greatly affects voltage of the energy storage apparatus 1. For this reason, estimation accuracy can be improved by using the present estimation method. By edge computing in which simulation is executed by the estimation device 2 in the energy storage apparatus 1, proper estimation can be performed in substantially real time with small delay time.

The estimation method, the estimation device, and the program can be applied to an application other than a vehicle, and may be applied to a flying body such as an aircraft, a flying vehicle, a high altitude platform station (HAPS), or the like, or may be applied to a ship or a submarine. The estimation method, the estimation device, and the program are preferably applied to a mobile body requiring high safety (requiring real-time calculation), but may be applied not only to a mobile body but also to a stationary energy storage apparatus.

It is to be understood that the embodiment disclosed herein is illustrative in all respects and not restrictive. The technical features described in examples can be combined with each other, and the scope of the present invention is intended to include all modifications within the claims and the scope equivalent to the claims.

The sequence described in the above embodiment is not limited, and processing procedures may be executed in a changed order within a range in which there is no contradiction in processing content, and a plurality of pieces of processing may be executed in parallel.

### DESCRIPTION OF REFERENCE SIGNS

1: energy storage apparatus
2: estimation device
21: control unit
22: storage unit
23: input and output unit
221: program
222: estimation data
M: recording medium
3: energy storage device

1. An estimation device comprising:
a control unit that estimates charge acceptance performance or discharge performance of an energy storage apparatus including a plurality of energy storage devices and a conductive member, wherein
the control unit
acquires a current value of the energy storage apparatus and a voltage value of the plurality of energy storage devices at an estimation time point, and
estimates information on whether or not the energy storage apparatus can be charged or discharged according to an assumed conduction pattern for a predetermined time from the estimation time point, by using the acquired current value, the acquired voltage value, and an energy storage apparatus model simulating behavior of the energy storage apparatus, the energy storage apparatus model including a resistance component of the conductive member.

2. The estimation device according to claim 1, wherein
the estimation device estimates an allowable current value of the energy storage apparatus by using the energy storage apparatus model and lower limit voltage or upper limit voltage of the energy storage apparatus.

3. The estimation device according to claim 1 or 2, wherein
the estimation device gives a smallest one of an allowable current value of the energy storage apparatus, an allowable current value of each energy storage device estimated using an energy storage device model simulating behavior of each energy storage device, and an absolute value of each protection current value for the energy storage apparatus to the energy storage apparatus model to obtain a voltage value of the energy storage apparatus after conduction in the assumed conduction pattern.

4. The estimation device according to any one of claims 1 to 3, wherein
the resistance component of the conductive member is set according to at least any of temperature of the energy storage apparatus, the current value of the energy storage apparatus, and a drive voltage of a semiconductor switch which is a circuit breaker.

5. The estimation device according to any one of claims 1 to 3, wherein
the energy storage apparatus model includes a DC resistance component of each energy storage device.

6. An energy storage apparatus comprising:
the estimation device according to any one of claims 1 to 4; and
a plurality of energy storage devices.

7. The energy storage apparatus according to claim 6, wherein
the energy storage apparatus is a 12 V battery, 24 V battery, or 48 V battery.

8. An estimation method for estimating charge acceptance performance or discharge performance of an energy storage apparatus including a plurality of energy storage devices and a conductive member, the estimation method comprising:
acquiring a current value of the energy storage apparatus and a voltage value of the plurality of energy storage devices at an estimation time point; and
estimating information on whether or not the energy storage apparatus can be charged or discharged according to an assumed conduction pattern for a predetermined time from the estimation time point, by using the acquired current value, the acquired voltage value, and an energy storage apparatus model simulating behavior of the energy storage apparatus, the energy storage apparatus model including a resistance component of the conductive member.

9. A program for causing a computer that estimates charge acceptance performance or discharge performance of an energy storage apparatus including a plurality of energy storage devices and a conductive member to execute processing of
acquiring a current value and a voltage value of the plurality of energy storage devices at an estimation time point; and
estimating information on whether or not the energy storage apparatus can be charged or discharged according to an assumed conduction pattern for a predetermined time from the estimation time point, by using the acquired current value, the acquired voltage value, and an energy storage apparatus model simulating behavior of the energy storage apparatus, the energy storage apparatus model including a resistance component of the conductive member.
